(19) United States
(12) Patent Application Publication
(10) Pub. No.: US 2022/0028670 A1
(43) Pub. Date: Jan. 27, 2022

(54) PLASMA PROCESSING METHOD AND PLASMA PROCESSING APPARATUS

(71) Applicant: Tokyo Electron Limited, Tokyo (JP)

(72) Inventor: Yuya Minoura, Kurokawa-gun (JP)

(21) Appl. No.: 17/380,277

(22) Filed: Jul. 20, 2021

(30) Foreign Application Priority Data
Jul. 21, 2020 (JP) 2020-124701

(51) Int. Cl. H01J 37/32; H01L 21/311; C23C 16/44

(52) U.S. Cl. CPC H01J 37/32862; H01L 21/31116; H01J 2237/332; C23C 16/4405; H01J 2237/3341; H01L 21/31144

(57) ABSTRACT

A plasma processing method includes carrying a substrate into a processing vessel and placing the substrate on a placing surface of a placing table within the processing vessel; performing a plasma processing on the substrate by forming plasma from a first gas within the processing vessel; forming, by forming plasma from a second gas within the processing vessel, a film covering a surface of a reaction product attached to a surface of a member within the processing vessel when the plasma processing is performed; and carrying-out the substrate on the placing surface of the placing table from the processing vessel in a state that the film is formed on the surface of the member within the processing vessel.

### CROSS-REFERENCE TO RELATED APPLICATION

This application claims the benefit of Japanese Patent Application No. 2020-124701 filed on Jul. 21, 2020, the entire disclosure of which is incorporated herein by reference.

### TECHNICAL FIELD

The various aspects and embodiments described herein pertain generally to a plasma processing method and a plasma processing apparatus.

### BACKGROUND

Conventionally, there is known a plasma processing apparatus configured to perform a plasma processing on a substrate such as a semiconductor wafer by using plasma. This plasma processing apparatus has a placing table for placing the substrate thereon within a processing vessel capable of forming, for example, a vacuum space therein. A lifter pin is accommodated within the placing table. In this plasma processing apparatus, to carry out the substrate after being subjected to the plasma processing from the processing vessel, the lifter pin is protruded from the placing table by a driving device, and the substrate is raised from a placing surface of the placing table by the lifter pin. Further, in the plasma processing apparatus, the plasma processing may be performed in the state that the placing table is cooled to a temperature equal to or lower than 0° C.
Patent Document 1: Japanese Patent Laid-open Publication No. 2016-207840
Patent Document 2: Japanese Patent Laid-open Publication No. 2017-103388

### SUMMARY

In one exemplary embodiment, a plasma processing method includes carrying a substrate into a processing vessel and placing the substrate on a placing surface of a placing table within the processing vessel; performing a plasma processing on the substrate by forming plasma from a first gas within the processing vessel; forming, by forming plasma from a second gas within the processing vessel, a film covering a surface of a reaction product attached to a surface of a member within the processing vessel when the plasma processing is performed; and carrying-out the substrate on the placing surface of the placing table from the processing vessel in a state that the film is formed on the surface of the member within the processing vessel.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a flowchart illustrating an example flow of a plasma processing method according to an exemplary embodiment;

FIG. 2A is a diagram for describing an example state within a processing vessel when the plasma processing method according to the exemplary embodiment is performed;

FIG. 2B is a diagram for describing an example state within the processing vessel when the plasma processing method according to the exemplary embodiment is performed;

FIG. 2C is a diagram for describing an example state within the processing vessel when the plasma processing method according to the exemplary embodiment is performed;

FIG. 2D is a diagram for describing an example state within the processing vessel when the plasma processing method according to the exemplary embodiment is performed;

FIG. 3 is a diagram illustrating an example of a comparison result of states of films exposed on substrates which are exposed to plasma of different kinds of gases;

FIG. 4 is a diagram illustrating an example of a comparison result of a state of a film exposed on a substrate after being subjected to a processing according to a comparative example 1 and a state of a film exposed on a substrate after being subjected to a processing according to an experimental example 1;

FIG. 5 is a diagram illustrating an example of an experimental result of investigating a relationship between a thickness of a protective film and presence or absence of a trouble in cleaning of the inside of the processing vessel; and

FIG. 6 is a diagram illustrating an example of a plasma processing apparatus in which the plasma processing method according to the exemplary embodiment is performed.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, various exemplary embodiments will be described in detail with reference to the accompanying drawings. Further, in the various drawings, same or corresponding parts will be assigned same reference numerals.

In a plasma processing apparatus, when a plasma processing is performed on a substrate, a reaction product is generated, and this generated reaction product may be attached to and deposited on an inner wall of a processing vessel or the like. A part of the reaction product deposited on the inner wall of the processing vessel or the like may be volatilized (separated) from the reaction product to float within the processing vessel as a gas, ending up being attached to a placing surface of a placing table again. For example, in the plasma processing apparatus, if the substrate after being subjected to the plasma processing is taken out of the processing vessel, the placing surface of the placing table is exposed within the processing vessel, and the reaction product may adhere to the exposed placing surface of the placing table. Particularly, if the plasma processing is performed in the state that the placing table is cooled to a temperature equal to or lower than 0° C., the reaction product floating as the volatile gas may be easily condensed and thus easily attached to the placing surface of the placing table. The adhesion of the reaction product to the placing surface of the placing table is regarded as a problem as it causes an error such as a failure in attracting the substrate onto the placing surface of the placing table.

[Example Flow of Plasma Processing Method According to Exemplary Embodiment]

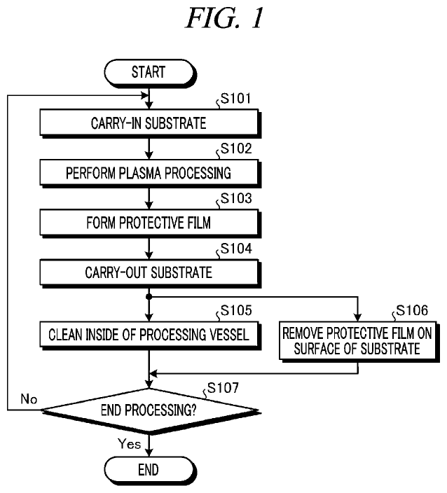

FIG. 1 is a flowchart illustrating an example flow of a plasma processing method according to an exemplary embodiment.

First, a substrate is carried into to a processing vessel (process S101). For example, the substrate is carried into the processing vessel and placed on a placing surface of a placing table within the processing vessel.

Then, by forming plasma from a first gas within the processing vessel, a plasma processing upon the substrate is performed (process S102). The plasma processing upon the substrate is carried out in the state that the placing table is maintained at a temperature equal to or lower than, e.g., 0° C. The plasma processing upon the substrate may be, for example, an etching processing. As the plasma processing is performed on the substrate, a reaction product adheres to a surface of a member within the processing vessel. Here, the member within the processing vessel may be a member including, for example, an inner wall of the processing vessel or the like.

Subsequently, by forming plasma from a second gas within the processing vessel, a protective film is formed on the surface of the member within the processing vessel (process S103). The protective film covers a surface of the reaction product attached to the surface of the member within the processing vessel when the plasma processing is performed. At this time, a surface of the substrate on the placing surface of the placing table as well as the surface of the reaction product is covered with the protective film.

Thereafter, in the state that the protective film is formed on the surface of the member within the processing vessel, the substrate on the placing surface of the placing table is carried out of the processing vessel (process S104).

If the substrate is taken out of the processing vessel, a cleaning process is performed in the processing vessel (process S105). In this cleaning process, for example, a dummy substrate is carried into the processing vessel and placed on the placing surface of the placing table. Then, by forming plasma from a third gas within the processing vessel, the reaction product adhering to the surface of the member within the processing vessel is removed along with the protective film.

The substrate taken out of the processing vessel is carried into a processing vessel of another apparatus capable of performing an ashing processing or a wet etching processing. Then, by performing the ashing processing or the wet etching processing within the processing vessel of this apparatus, the protective film covering the surface of the substrate is removed (process S106). At this time, if a carbon-containing mask such as amorphous carbon or a resist is used as a mask on the substrate, this mask on the substrate is also removed along with the protective film covering the substrate.

Then, it is determined whether or not to end the processing (process S107). If it is determined not to end the processing (process S107: No), the processing returns back to the process S101, and a next substrate to be processed is carried into the processing vessel, and the processing up to the process 106 is repeated. On the other hand, if it is determined that the processing is to be ended (process 107: Yes), the processing is ended.

Further, the determination in the process S107 is performed based on, for example, whether the number of substrates after being subjected to the plasma processing has reached a preset number.

[State within Processing Vessel when Performing Plasma Processing Method According to Exemplary Embodiment]

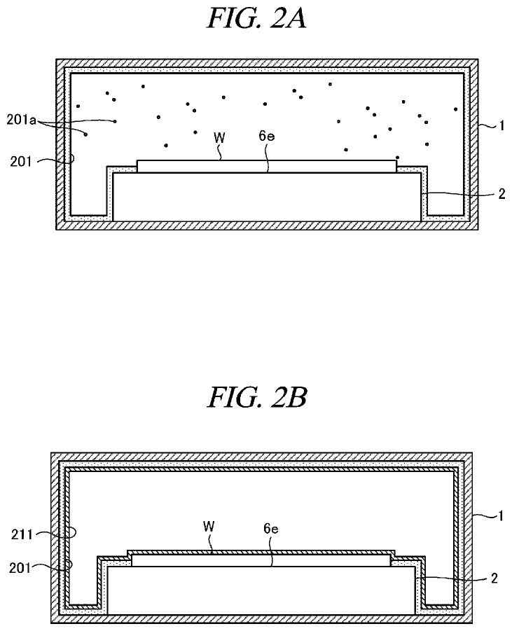

FIG. 2A to FIG. 2D are diagrams for describing an example of states within the processing vessel when the plasma processing method according to the exemplary embodiment is performed. Referring to FIG. 2A to FIG. 2D, the plasma processing method according to the exemplary embodiment will be further explained.

FIG. 2A illustrates a state in which a reaction product 201 is attached to surfaces of members within a processing vessel 1 as the plasma processing of the process S102 is performed. In FIG. 2A, the reaction product 201 is illustrated to be attached on surfaces of the members within the processing vessel 1, i.e., an inner wall of the processing vessel 1 and a sidewall of a placing table 2 within the processing vessel 1. Further, a part of the reaction product 201 attached to the members within the processing vessel 1 is volatilized (separated) therefrom to float within the processing vessel 1 as a volatile gas 201a. Here, if a substrate W after being subjected to the plasma processing is taken out of the processing vessel 1 in the state of FIG. 2A, a placing surface 6e of the placing table 2 is exposed within the processing vessel 1, and the volatile gas 201a is attracted toward the exposed placing surface 6e of the placing table 2. As a result, there is a likelihood that a reaction product originated from the volatile gas 201a may adhere to the exposed placing surface 6e of the placing table 2. Particularly, if the plasma processing of the process S102 is performed in the state that the placing table 2 is cooled to a temperature equal to or lower than 0° C., the reaction product floating as the volatile gas 201a may be easily condensed, and the reaction product originated from the volatile gas 201a may be easily attached to the placing surface 6e of the placing table 2. The adhesion of the reaction product to the placing surface 6e of the placing table 2 is regarded as being problematic as it causes an error such as a failure in attracting the substrate W onto the placing surface 6e of the placing table 2.

As a resolution, in the exemplary embodiment, a protective film 211 is formed on the surfaces of the members within the processing vessel 1 to cover a surface of the reaction product 201 (process S103, FIG. 2B), after performing the plasma processing of the process S102. That is, by forming the plasma from the second gas within the processing vessel 1, the protective film 211 is formed on the surfaces of the members within the processing vessel 1. The protective film 211 covers the surface of the substrate W on the placing surface 6e of the placing table 2 as well as the surface of the reaction product 201. Then, in the state that the protective film 211 is formed on the surfaces of the members within the processing vessel 1, the substrate W on the placing surface 6e of the placing table 2 is carried out of the processing vessel 1 (process S104).

As stated above, by forming the protective film 211 on the surfaces of the members within the processing vessel 1 to cover the surface of the reaction product 201 after performing the plasma processing of the process S102, the adhesion of the reaction product to the placing surface 6e of the placing table 2 exposed when the substrate W is carried out can be reduced. By way of example, if the substrate W on the placing surface 6e of the placing table 2 is taken out of the processing vessel 1, the placing surface 6e of the placing table 2 is exposed within the processing vessel 1, as illustrated in FIG. 2C. In FIG. 2C, however, since the surface of the reaction product 201 is covered with the protective film 211 formed thereof, the volatile gas 201a (see FIG. 2A) volatilized (separated) from the reaction product 201 is blocked by the protective film 211. Accordingly, the floating of the volatile gas 201a within the processing vessel 1 can be suppressed, and, as a result, the adhesion of the reaction product to the placing surface 6e of the placing table 2 can be reduced.

After the substrate W is taken out of the processing vessel 1, a cleaning process is performed in the processing vessel 1 (process S105, FIG. 2D). In the cleaning process, a dummy substrate W′ is carried into the processing vessel 1 and placed on the placing surface 6e of the placing table 2. Then, by forming the plasma from the third gas within the processing vessel 1, the reaction product 210 attached to the surfaces of the members within the processing vessel 1 is removed along with the protective film 211. Further, the cleaning process may be performed by forming the plasma from the third gas within the processing vessel 1 without carrying the dummy substrate W′ into the processing vessel 1. Meanwhile, after the substrate W is carried out of the processing vessel 1, the protective film 211 covering the surface of the substrate W is removed (process S106). At this time, if a carbon-containing mask such as amorphous carbon or a resist is used as a mask on the substrate W, the mask on the substrate W as well as the protective film 211 covering the surface of the substrate W is removed.

[Selection of Second Gas for Use in Forming Protective Film]

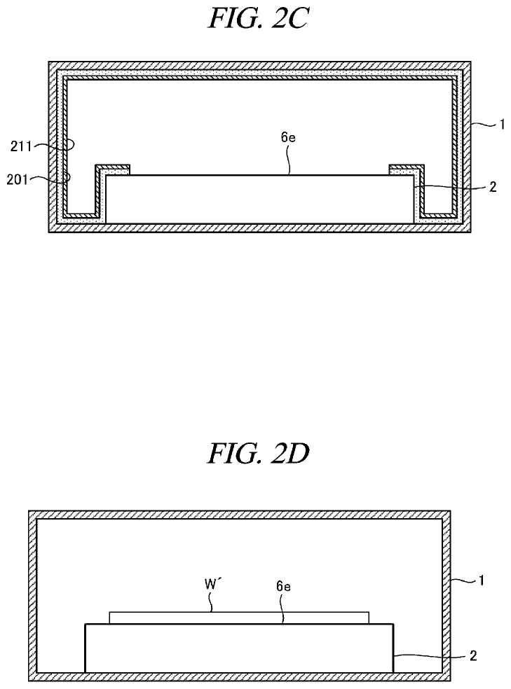

It is desirable that the second gas for use in forming the protective film is a gas which does not serve as an etchant for surfaces (a top surface and a side surface) of the film on the substrate exposed as a result of performing the plasma processing of the process S102 on the substrate. On this ground, the present inventors have investigated whether various kinds of gases have a function as the etchant for the surfaces of the film exposed on the substrate. In an experiment, a substrate having, as the film exposed on the substrate, a silicon oxide film (hereinafter, referred to as “SiO₂ film”) stacked on a silicon substrate is exposed to plasma of CF₄, CH₄ and C₄F₈. The SiO₂ film is provided with a pattern. FIG. 3 is a diagram illustrating an example of a comparison result of states of the etching target film on the substrate which is exposed to the plasma of the different kinds of gases. In FIG. 3, ‘Initial’ shows the substrate provided with the pattern of a hole shape which is formed by performing the plasma processing (etching) of the process S102 through a mask having an opening formed on the SiO₂ film. Further, for the simple illustration of an experimental result, the substrate is illustrated to be free of the mask after the etching processing, and the top surface and the side surface of the SiO₂ film are exposed.

As depicted in FIG. 3, when CF₄ or C₄F₈ is used, the SiO₂ film exposed on the substrate is cut, and a film thickness thereof decreases. In contrast, if CH₄ is used, a deposit is deposited on the top surface of the SiO₂ film on the substrate and on a bottom of the pattern of the SiO₂ film. As can be seen from the result of FIG. 3, it is possible to maintain the shape of the pattern of the film exposed on the substrate by using a carbon-containing gas without containing halogen. That is, the second gas for use in forming the protective film is desirably a carbon-containing gas without containing halogen, and, more desirably, a hydrocarbon gas.

Further, in the above-described exemplary embodiment, it is assumed that the plasma processing upon the substrate in the process S102 is the etching processing, and the etching target film and the film exposed on the substrate after the etching processing are the SiO₂ films. However, the present exemplary embodiment can be applied to various other kinds of etching target films as well. By way of example, the etching target film may be a monolayer such as a silicon nitride film (SiN film) or a silicon carbide film (SiC film), or a stacked film (ON stacked film) in which a silicon oxide film and a silicon nitride film are alternately stacked on top of each other. Further, the etching target film may be a silicon film such as a monocrystalline silicon (Si), a polycrystalline silicon (Poly-Si) or amorphous silicon (αSi), or a stacked film (OP stacked film) in which a silicon oxide film and a polycrystalline silicon are alternately stacked on top of each other. Further, the etching target film may be a low-dielectric film having a SiOCH structure. All of these various films will be referred to as “silicon-containing film” generically. Further, if the etching target film is etched to reach an underlying film, the underlying film is exposed. A metal film such as titanium (Ti), tungsten (W), or copper (Cu), or a silicon film may be used as the underlying film. A metal film such as titanium nitride (TiN) or tungsten (W), or a silicon film is used as a mask for the etching, and the mask is exposed on the substrate after the etching processing.

For the silicon-containing film and the metal film, it is desirable that the second gas for use in forming the protective film is a gas which does not serve as the etchant, the same as described in the case of the SiO₂ film. Further, it is known that the silicon-containing film and the metal film are easily cut in an environment in which halogen is included. Thus, if the film exposed on the substrate is the silicon-containing film or the metal film, it is desirable that, the second gas for use in forming the protective film is the carbon-containing gas without containing halogen, more desirably, the hydrocarbon gas, the same as in the case of the SiO₂ film.

[Removal of Protective Film]

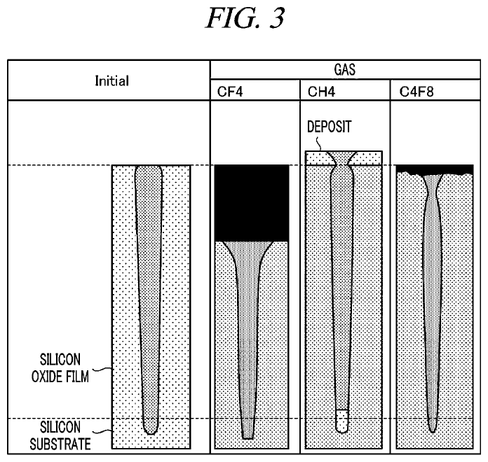

As mentioned above, the protective film covering the surface of the substrate is removed after the substrate is carried out of the processing vessel (process S106). Further, in case that the carbon-containing mask is used as the mask on the substrate, the mask on the substrate as well as the protective film is removed. The present inventors have performed the etching processing on the substrate according to the plasma processing method of the exemplary embodiment, and have investigated the pattern shape of the etching target film after the mask is removed, that is, the pattern shape of the film exposed on the substrate. FIG. 4 is a diagram showing an example of a comparison result of a state of an etching target film on a substrate after a processing according to a comparative example 1 and a state of an etching target film on a substrate after a processing according to a first experimental result. In FIG. 4, ‘Etch→Depo→Ash’ shows the result of the experimental example 1 where the substrate is etched by the plasma processing method according to the exemplary embodiment and the mask is then removed. Further, ‘Etch→Ash’ shows the result of the comparative example 1 where the substrate is etched without forming the protective film and the mask is then removed. Furthermore, in the experiments, the used substrate has the SiO₂ film as the etching target film on the silicon substrate. In addition, the mask on the substrate is the carbon-containing mask, and this mask is removed by using plasma of oxygen in the process S106.

As depicted in FIG. 4, the pattern shape of the etching target film after the processing according to the experimental example 1, that is, the pattern shape of the film exposed on the substrate is found to be substantially identical to the pattern shape of the etching target film after the processing according to the comparative example 1. As cane be seen from the result of FIG. 4, the protective film covering the surface of the substrate is appropriately removed along with the mask (that is, the carbon-containing mask) on the substrate.

[Minimum Film Thickness of Protective Film]

Assume that the protective film formed on the surfaces of the members within the processing vessel is thin. In such a case, even if the protective film is formed, the reaction product originated from the volatile gas may attach to the placing surface of the placing table as the volatile gas separated from the reaction product penetrates the protective film to float within the processing vessel. In this regard, a relationship between a thickness of the protective film and presence or absence of a trouble in cleaning of the inside of the processing vessel is investigated.

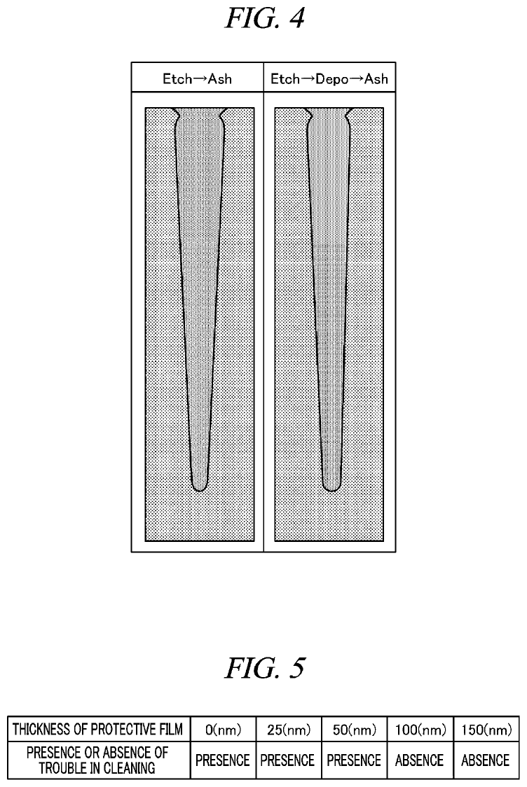

FIG. 5 is a diagram illustrating an example of an experimental result of investigating the relationship between a thickness of the protective film and presence or absence of a trouble in cleaning of the inside of the processing vessel. In an experiment shown in FIG. 5, the thickness of the protective film formed in the process S103 is set to be of five different values, and the presence or absence of the trouble is inspected by measuring a leak amount of a heat transfer gas (He gas) supplied into a gap between the placing surface of the placing table and the dummy substrate during the cleaning of the process S105. The thickness of the protective film is set to be of the five different values: 0 nm, 25 nm, 50 nm, 100 nm and 150 nm. Further, a time during which the substrate on the placing surface of the placing table is taken out of the processing vessel in the process S104 and the dummy substrate is carried into the processing vessel to be placed on the placing surface of the placing table in the process 105 is set to be 600 seconds. This time is sufficiently longer than a time typically taken to take out the substrate and to carry in the dummy substrate. If the leak amount of the heat transfer gas supplied into the gap between the placing surface of the placing table and the dummy substrate exceeds a preset tolerance value, it is determined that the trouble has occurred. If, however, the leak amount of the heat transfer gas is equal to or less than the tolerance value, it is determine that no trouble has occurred. As for the reason for this, if the reaction product adheres to the placing surface of the placing table, an attracting force by which the dummy substrate is attracted to the placing surface of the placing table is reduced, resulting in an increase of the leak amount of the heat transfer gas.

As shown in FIG. 5, when the thickness of the protective film is equal to or larger than 100 nm, no trouble has been found in the cleaning of the inside of the processing vessel. That is, as found out from the result of FIG. 5, if the thickness of the protective film is equal to or larger than 100 nm, the volatile gas cannot penetrate the protective film and, thus, the adhesion of the reaction product originated from the volatile gas to the placing surface of the placing table is suppressed. Thus, it is desirable that the protective film is formed to have the thickness equal to or larger than 100 nm.

[Example of Plasma Processing Apparatus According to Exemplary Embodiment]

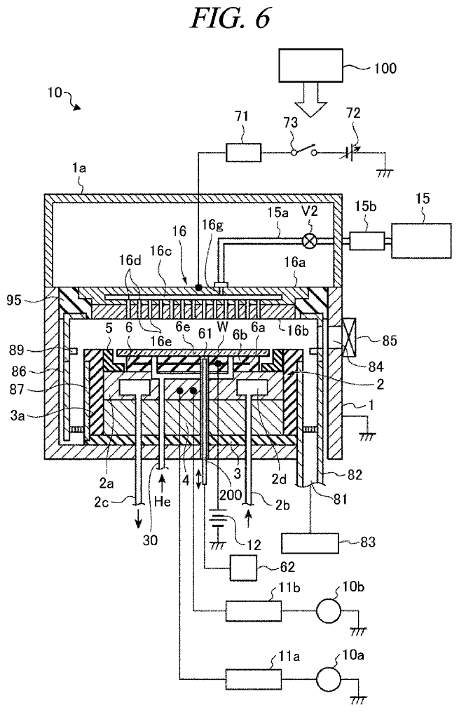

FIG. 6 is a diagram illustrating an example of a plasma processing apparatus 10 in which the plasma processing method according to the exemplary embodiment is performed. The plasma processing apparatus 10 has the processing vessel 1 which is hermetically sealed and electrically grounded. This processing vessel 1 is of a cylindrical shape and is made of, by way of non-limiting example, aluminum. The processing vessel 1 forms therein the processing space in which the plasma is formed. The placing table 2 configured to hold thereon the substrate W such as a semiconductor wafer W horizontally is provided within the processing vessel 1. The placing table 2 includes a base 2a and an electrostatic chuck (ESC) 6. The base 2a is made of a conductive metal such as, but not limited to, aluminum, and serves as a lower electrode. The electrostatic chuck 6 has a function of attracting the substrate W electrostatically. The placing table 2 is supported by a supporting table 4. The supporting table 4 is supported by a supporting member 3 which is made of, by way of non-limiting example, quartz. Further, a focus ring 5 made of, for example, monocrystalline silicon is provided on an upper peripheral portion of the placing table 2. Further, a cylindrical inner wall member 3a made of, for example, quartz is provided within the processing vessel 1 to surround the placing table 2 and the supporting table 4.

The base 2a is connected to a first RF power supply 10a via a first matching device 11a, and also connected to a second RF power supply 10b via a second matching device 11b. The first RF power supply 10a is for plasma formation, and is configured to supply a high frequency power having a predetermined frequency to the base 2a of the placing table 2. Further, the second RF power supply 10b is for ion attraction (bias), and is configured to supply a high frequency power having a frequency lower than that of the first RF power supply 10a to the base 2a of the placing table 2. In this way, the placing table 2 is configured such that a voltage is applicable thereto. Meanwhile, a shower head 16 serving as an upper electrode is disposed above the placing table 2, facing the placing table 2 in parallel. The shower head 16 and the placing table 2 serve as a pair of electrodes (the upper electrode and the lower electrode).

The electrostatic chuck 6 has a top surface having a flat disk shape, and this top surface is configured as the placing surface 6e on which the substrate W is placed. The electrostatic chuck 6 includes an electrode 6a embedded in an insulator 6b, and the electrode 6a is connected with a DC power supply 12. As a DC voltage is applied to the electrode 6a from the DC power supply 12, the substrate W is attracted by a Coulomb force.

A coolant path 2d is formed within the placing table 2, and a coolant inlet line 2b and a coolant outlet line 2c are connected to the coolant path 2d. By circulating an appropriate coolant, for example, cooling water within the coolant path 2d, the placing table 2 can be regulated to a preset temperature. Further, a gas supply line 30 for supplying a cold heat transfer gas (backside gas) such as a helium gas to a rear surface of the substrate W is formed to penetrate the placing table 2 and the like, and the gas supply line 30 is connected to a non-illustrated gas source. With these configurations, the substrate W attracted to and held on the top surface of the placing table 2 by the electrostatic chuck 6 is controlled to a predetermined temperature.

The placing table 2 is provided with, a plurality of, for example, three pin through holes 200 (only one is shown in FIG. 6), and lifter pins 61 are respectively disposed within the pin through holes 200. The lifter pins 61 are connected to an elevating device 62. The elevating device 62 is configured to move the lifter pins 61 up and down, thus allowing the lifter pins 61 to be protruded above or retracted below the placing surface 6e of the placing table 2. In the state that the lifter pins 61 are raised, leading ends of the lifter pins 61 are protruded from the placing surface 6e of the placing table 2, allowing the substrate W to be held above the placing surface 6e of the placing table 2. Meanwhile, if the lifter pins 61 are lowered, the leading ends of the lifter pins 61 are accommodated within the pin through holes 200, and the substrate W is placed on the placing surface 6e of the placing table 2. As stated, the elevating device 62 moves the substrate W up and down with respect to the placing surface 6e of the placing table 2 by the lifter pins 61. Further, in the state that the lifter pins 61 are raised by the elevating device 62, the substrate W is held above the placing surface 6e of the placing table 2 by the lifter pins 61.

The aforementioned shower head 16 is provided at a ceiling portion of the processing vessel 1. The shower head 16 includes a main body 16a and an upper ceiling plate 16b forming an electrode plate. The shower head 16 is supported at an upper portion of the processing vessel 1 with an insulating member 95 therebetween. The main body 16a is made of a conductive material such as, but not limited to, aluminum having an anodically oxidized surface, and is configured to support the upper ceiling plate 16b on a bottom surface thereof in a detachable manner.

A gas diffusion space 16c is provided within the main body 16a. Further, a multiple number of gas through holes 16d are formed in a bottom portion of the main body 16a to be located under the gas diffusion space 16c. The upper ceiling plate 16b is provided with gas inlet holes 16e which are formed through the upper ceiling plate 16b in a thickness direction thereof to be respectively overlapped with the gas through holes 16d. With this configuration, a processing gas introduced into the gas diffusion space 16c is supplied into the processing vessel 1 through the gas through holes 16d and the gas inlet holes 16e while being distributed in a shower shape.

The main body 16a is provided with a gas inlet opening 16g through which the processing gas is introduced into the gas diffusion space 16c. One end of a gas supply line 15a is connected to the gas inlet opening 16g, and the other end of this gas supply line 15a is connected to a processing gas source (gas supply) 15 configured to supply the processing gas. The gas supply line 15a is provided with a mass flow controller (MFC) 15b and an opening/closing valve V2 in sequence from the upstream side. Various kinds of processing gases are supplied into the gas diffusion space 16c from the processing gas source 15 through the gas supply line 15a. The processing gas source 15 has a multiple number of gas sources. These gas sources may include sources of various kinds of gases such as a source of a hydrocarbon gas, a source of a gas containing an oxygen atom (for example, an oxygen gas), and a source of an inert gas. As the inert gas, a nitrogen gas, an Ar gas, a He gas, or the like may be used. With this configuration, the plasma processing apparatus 10 is capable of supplying a gas (gases) from one or more gas sources selected from the multiple number of gas sources of the processing gas source 15 into the processing vessel 1 at individually controlled flow rates.

The aforementioned shower head 16 serving as the upper electrode is electrically connected with a variable DC power supply 72 via a low pass filter (LPF) 71. This variable DC power supply 72 is configured to turn on/off a power feed with an on/off switch 73. A current/voltage of the variable DC power supply 72 and an on/off operation of the on/off switch 73 are controlled by a controller 100 to be described later. Further, as will be described later, when the plasma is formed in the processing space as the high frequency powers from the first RF power supply 10a and the second RF power supply 10b are applied to the placing table 2, the on/off switch 73 is turned on by the controller 100 when necessary, and a preset DC voltage is applied to the shower head 16 serving as the upper electrode.

A cylindrical grounding conductor 1a extends upwards from a sidewall of the processing vessel 1 to be higher than a height position of the shower head 16. This cylindrical grounding conductor 1a has a ceiling wall at a top portion thereof.

An exhaust port 81 is formed at a bottom of the processing vessel 1. The exhaust port 81 is connected to an exhaust device 83 via an exhaust line 82. The exhaust device 83 has a vacuum pump, and is configured to decompress the processing vessel 1 to a preset vacuum level by operating the vacuum pump. Meanwhile, a carry-in/out opening 84 for the substrate W is formed at the sidewall of the processing vessel 1, and a gate valve 85 configured to open or close the carry-in/out opening 84 is provided at the carry-in/out opening 84.

Inside the sidewall of the processing vessel 1, a deposition shield 86 is provided along an inner wall surface of the processing vessel 1. The deposition shield 86 is configured to suppress an etching byproduct (deposit) from adhering to the processing vessel 1. A conductive member (GND block) 89, which is connected such that a potential thereof with respect to the ground is controllable, is disposed at the deposition shield 86 substantially on a level with the substrate W. With this configuration, an abnormal discharge is suppressed. Further, a deposition shield 87 extending along the inner wall member 3a is provided at a lower end portion of the deposition shield 86. The deposition shields 86 and 87 are provided in a detachable manner.

Further, the plasma processing apparatus 10 is equipped with, as depicted in FIG. 6, for example, the controller 100 including a processor, a memory, and so forth. The controller 100 controls the individual components of the plasma processing apparatus 10. Specifically, the controller 100 controls, by using controls signals, the selection of the gas from the processing gas source 15 and the flow rate of the selected gas, the gas exhaust by the exhaust device 83, the power supply from the first and second RF power supplies 10a and 10b, the voltage application from the variable DC power supply 72, the elevation of the lifter pins 61, and so forth. Further, the individual processes of the plasma processing method disclosed in the present specification may be implemented as the individual components of the plasma processing apparatus 10 are operated under the control of the controller 100. A computer program for implementing the plasma processing method according to the exemplary embodiment and various data for use in implementing the corresponding method are stored in the memory of the controller 100 to be read out.

[Effects of Exemplary Embodiment]

A plasma processing method according to the exemplary embodiment includes carrying a substrate into a processing vessel and placing the substrate on a placing surface of a placing table within the processing vessel; performing a plasma processing on the substrate by forming plasma from a first gas within the processing vessel to; forming, by forming plasma from a second gas within the processing vessel, a film covering a surface of a reaction product attached to a surface of a member within the processing vessel when the plasma processing is performed; and carrying-out the substrate on the placing surface of the placing table from the processing vessel in a state that the film is formed on the surface of the member within the processing vessel. Accordingly, the adhesion of the reaction product to the placing surface of the placing table can be suppressed.

Further, in the present exemplary embodiment, the plasma processing method may further include, after the carrying-out of the substrate, removing the reaction product along with the film by forming plasma from a third gas within the processing vessel. Accordingly, the protective film covering the surface of the reaction product and the reaction product can be removed at the same time.

Furthermore, in the forming of the film, a surface of the substrate as well as the surface of the reaction product may be covered with the film. Further, in the exemplary embodiment, the plasma processing method may further include, after the carrying-out of the substrate, removing a mask on the substrate along with the film covering the surface of the carried-out substrate. Accordingly, the protective film covering the surface of the substrate and the mask on the substrate can be appropriately removed together, and, as a result, the pattern shape under the mask can be maintained.

In addition, in the exemplary embodiment, the second gas may be a gas which does not serve as an etchant for a film exposed on the substrate. Accordingly, the pattern shape of the film exposed on the substrate can be maintained in the forming of the protective film.

Moreover, in the exemplary embodiment, the film exposed on the substrate is a silicon oxide film (SiO2 film), and the second gas may be a carbon-containing gas without containing halogen. Furthermore, in the exemplary embodiment, the second gas may be a hydrocarbon gas. Thus, the pattern shape of the SiO2 film which is exposed on the substrate can be maintained in the forming of the protective film.

Besides, in the forming of the film in the exemplary embodiment, the film may be formed on the surface of the member within the processing vessel to have a thickness equal to or larger than 100 nm. Accordingly, it is difficult for the volatile gas separated from the reaction product to penetrate the protective film, so that the reaction product originated from the volatile gas can be suppressed from adhering to the placing surface of the placing table.

Additionally, in the exemplary embodiment, a surface temperature of the member within the processing vessel is equal to or lower than a temperature of the placing table at the time when the plasma processing is performed. The gas separated from the film may not adhere to the surface of the member within the processing vessel. Accordingly, even if the surface temperature of the member within the processing vessel is low, the gas separated from the film can be suppressed from being attached to the surface of the member within the processing vessel.

It should be noted that the above-described exemplary embodiment is illustrative in all aspects and is not anyway limiting. The above-described exemplary embodiment may be omitted, replaced and modified in various ways without departing from the scope and the spirit of claims.

By way of example, in the present exemplary embodiment, the plasma processing apparatus 10 is configured as the capacitively coupled plasma processing apparatus. However, the plasma processing apparatus 10 may be any of various kinds of plasma processing apparatuses. For example, the plasma processing apparatus 10 may be any of various types such as an inductively coupled plasma processing apparatus and a plasma processing apparatus configured to excite a gas by a surface wave such as a microwave.

According to the exemplary embodiment, it is possible to reduce the adhesion of the reaction product to the placing surface of the placing table.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A plasma processing method, comprising:
carrying a substrate into a processing vessel and placing the substrate on a placing surface of a placing table within the processing vessel;
performing a plasma processing on the substrate by forming plasma from a first gas within the processing vessel;
forming, by forming plasma from a second gas within the processing vessel, a film covering a surface of a reaction product attached to a surface of a member within the processing vessel when the plasma processing is performed; and
carrying-out the substrate on the placing surface of the placing table from the processing vessel in a state that the film is formed on the surface of the member within the processing vessel.

2. The plasma processing method of claim 1, further comprising:
removing, after the carrying-out of the substrate, the reaction product along with the film by forming plasma from a third gas within the processing vessel.

3. The plasma processing method of claim 1,
wherein, in the forming of the film, a surface of the substrate as well as the surface of the reaction product is covered with the film, and
the plasma processing method further comprises, removing, after the carrying-out of the substrate, the film covering the surface of the substrate.

4. The plasma processing method of claim 1,
wherein the second gas is a gas which does not serve as an etchant for a surface of a film exposed on the substrate by the performing of the plasma processing.

5. The plasma processing method of claim 4,
wherein the film exposed on the substrate is a silicon-containing film or a metal film, and
the second gas is a carbon-containing gas without containing halogen.

6. The substrate processing method of claim 5,
wherein the second gas is a hydrocarbon gas.

7. The substrate processing method of claim 1,
wherein, in the forming of the film, the film is formed on the surface of the member within the processing vessel to have a thickness equal to or larger than 100 nm.

8. The substrate processing method of claim 1,
wherein a gas separated from the film does not adhere to a surface of the placing table when a temperature of the placing table is equal to a temperature at which the plasma processing is performed.

9. A plasma processing apparatus, comprising:
a processing vessel which provides a processing space therein;
a placing table, provided within the processing vessel, having a placing surface on which a substrate is placed;
a gas supply configured to supply a processing gas into the processing vessel; and
a controller,
wherein the controller controls individual components to perform a plasma processing method comprising:
carrying the substrate into the processing vessel and placing the substrate on the placing surface of the placing table within the processing vessel;
performing a plasma processing on the substrate by forming plasma from a first gas within the processing vessel;
forming, by forming plasma from a second gas within the processing vessel, a film covering a surface of a reaction product attached to a surface of a member within the processing vessel when the plasma processing is performed; and
carrying-out the substrate on the placing surface of the placing table from the processing vessel in a state that the film is formed on the surface of the member within the processing vessel.
